(19) United States
(12) Patent Application Publication
(10) Pub. No.: US 2018/0226357 A1
(43) Pub. Date: Aug. 9, 2018

(54) EMBEDDED VOLTAGE REFERENCE PLANE FOR SYSTEM-IN-PACKAGE APPLICATIONS

(71) Applicant: Intel Corporation, Santa Clara, CA (US)

(72) Inventors: Jackson Chung Peng Kong, Tanjung Tokong (MY); Bok Eng Cheah, Bukit Gambir (MY); Ping Ping Ooi, Butterworth (MY); Paik Wen Ong, Taiping (MY); Kooi Chi Ooi, Glugor (MY)

(21) Appl. No.: 15/889,471

(22) Filed: Feb. 6, 2018

(30) Foreign Application Priority Data
Feb. 8, 2017 (MY) PI 2017700433

(51) Int. Cl. H01L 23/552; H01L 23/498; H01L 23/00; H01L 21/48

(52) U.S. Cl. CPC H01L 23/552; H01L 23/49822; H01L 23/49866; H01L 2224/16225; H01L 23/49894; H01L 24/16; H01L 21/4857; H01L 23/49838

(57) ABSTRACT

A semiconductor package is disclosed. The semiconductor package includes a multilayer package substrate. The layers of the multi-layer substrate include one or more conductive layers to transmit information within the semiconductor package. The layers also include one or more conductive power supply layers to provide power to the semiconductor package and to one or more connected components. The layers also include one or more layers of dielectric material forming a substrate core dielectric. The layers also include an embedded reference plane within the substrate core dielectric, wherein the embedded reference plane is conductive and reduces electrical interference between the other conductive layers in the multilayer package substrate.

### PRIORITY APPLICATION

This application claims the benefit of priority to Malaysian Application Serial No. PI 2017700433, filed Feb. 8, 2017, which is incorporated herein by reference in its entirety.

### TECHNICAL FIELD

Embodiments described herein generally relate to improving a voltage reference in a system-in-package (SiP) application.

### BACKGROUND

Electronic devices have grown increasingly small and power efficient. As such, each component within an electronic device (e.g., a smart phone, laptop, tablet, or other size dependent device) needs to be developed in smaller sizes. In an effort to decrease the size of various electric components, a variety of strategies have been used. Thus, any strategy that enables further reduction in size is important.

One specific problem involves the core thickness in conventional packages or system-in-package devices. In such devices, reducing the thickness of the core (made of resin and/or fiberglass) results in undesired coupling of components on opposite sides of the core. Thus, the core remains at a certain thickness to prevent electromagnetic interference.

### BRIEF DESCRIPTION OF THE DRAWINGS

FIG. 1 is a cross-sectional diagram depicting a microelectronic package substrate in accordance with some example embodiments.

FIG. 2 is a cross-sectional diagram depicting a system with a reference plane embedded in the package substrate core layer in accordance with some example embodiments.

FIG. 3 is a cross-sectional diagram depicting a package substrate with an embedded reference plane in the package substrate core layer in accordance with an example embodiment.

FIGS. 4A-4F are a diagrams depicting steps in a process of fabricating a package substrate core layer with an embedded reference plane, in accordance with some example embodiments.

FIG. 5 shows a flow diagram of a method of fabricating a package substrate core layer with an embedded reference plane, in accordance with some example embodiments.

FIG. 6 illustrates a system-level diagram, according to one example embodiment.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

It is desirable to reduce the size of electronic components. One potential avenue for reducing the z-height (e.g., the profile) of a component is to lessen the thickness of the central core (e.g., made of resin or other non-conductive material). However, as noted above, as the overall size of components shrinks, reducing the size of a core can have the unwanted result of undesired coupling (e.g., electromagnetic interference).

To avoid unwanted electromagnetic interference, a metal layer (e.g., copper) is inserted within the package substrate core dielectric layer. This metal layer is used as a reference voltage for components on either side of the component. By adding a thin metal layer, the overall thickness of the core is able to be reduced without having any undesired coupling.

In some example embodiments, construction starts with a single metal layer (e.g., copper). Two non-conductive additional layers, one on top and one on bottom, are affixed to the metal layer. The non-conductive layers are composed of glass or fiber cloth that is hot-pressed to attach the glass or fiber cloth to both sides of the metal layer.

The glass cloth/metal foil stack is then encapsulated with dielectric materials, e.g., polyimide, polyamide, bismaleimide-Triazine resin, epoxy resins, polyurethanes, benzocyclobutene (BCB), high-density polyethylene (HDPE) through an impregnation process, e.g., a lamination or rolling process. The fiber/metal stack-reinforced-epoxy-resins core is then laminated with copper foils through a lamination and hot-press process.

Once the first three layers are in place (metal layer, dielectric layer, and another metal layer), holes are drilled through the layers (a first through-holes). This allows the top layer to be electrically and communicatively connected to the bottom layer. In some example embodiments, second through-holes are formed through a dielectric material deposited within the first through-holes.

To finish the package, metal is then electroplated into the first and second through-holes to connect the outer metal layers to the central metal layer and to the other side of the package. Signal distribution layers are then added using semi-additive processes such as photolithography, etching, electroplating, and surface finishing processes.

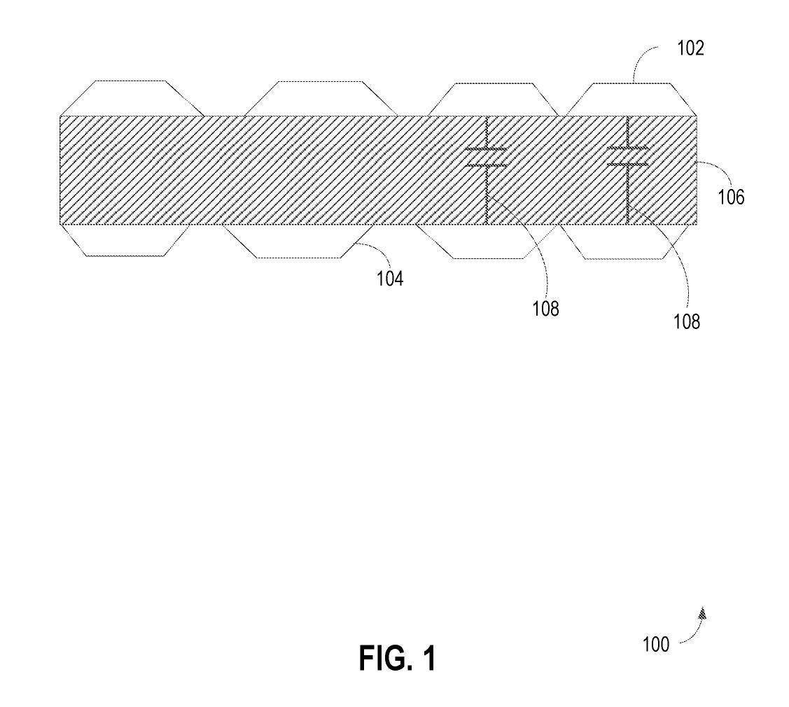

FIG. 1 is a cross-sectional diagram depicting a microelectronic package substrate 100 in accordance with some example embodiments. The package substrate 100 consists of two layers of signal conductors (e.g., top layer 102 and bottom layer 104) on each side of a core layer 106. In some example embodiments, the core layer 106 is a dielectric material such as resin.

However, this layout results in undesired radio frequency (RF) interference 108 between the top layer 102 and the bottom layer 104. Furthermore, core layer routing generally use larger trace width in order to meet targeted impedance based on the far distance to the voltage reference plane.

In some example embodiments, undesired interference in these signal conductors can result in an unacceptable level of errors in the signals. As such, it is desirable to be able to reduce the size of the core layer 106 without having a corresponding increase in RF interference and accompanying faults.

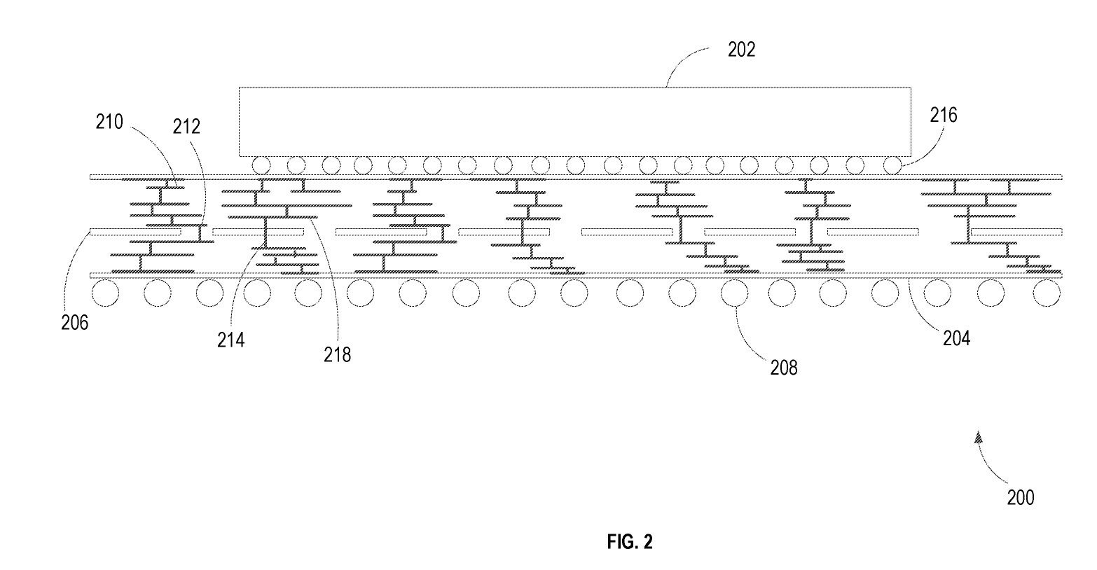

FIG. 2 is a cross-sectional diagram depicting a system 200 with a reference plane embedded in the package substrate core layer. The embedded reference plane is associated with one or more reference voltage traces through the through-holes.

As can be seen in the figure, the package includes a component 202 attached to a substrate 204 through solder bump connection 216. The substrate 204 is multilayered and has a series of signals 210 that transmit data and power through the package. In some example embodiments, some of the power and data signal routing lines pass through a through-hole without connecting to the embedded reference plane 214, such as at 212. In this case, the signal is not connected to the embedded reference plane (e.g. Vss or ground reference plane that associates with Vss reference voltage).

In other example embodiments, the substrate 204 has a series of reference voltage traces 218, i.e. conductors associate to a reference voltage such as Vss or ground. The reference voltage traces 218 are connected to the embedded reference plane 206. For example, reference number 214 shows a connection between reference voltage traces 218 and a section of the embedded reference plane. In other example embodiments, the embedded reference plane 206 may be associated to a power or Vcc reference voltage.

In some example embodiments, the system 200 is connected to another component via a ball grid array 208.

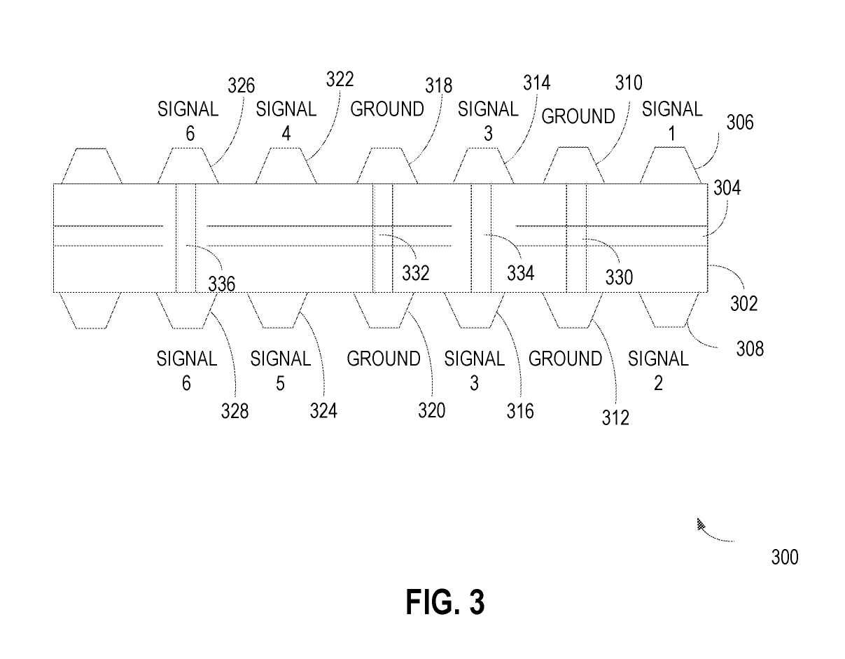

FIG. 3 is a cross-sectional diagram depicting a package substrate 300 with an embedded reference plane 304 in the package substrate core layer in accordance with an example embodiment. The package 300 includes a series of signal conductors (306-328) and an embedded reference plane 304 in the substrate or central core layer 302.

In this example, the system 300 includes a central core 302 comprised of a dielectric material, an embedded reference plane 304, and a series of signal conductors (306 to 328). The embedded reference plane 304 is made of copper or another suitable metal.

Some of the conductors are connected to plated through holes such as Vss or ground 310, 312, 318, and 320. Conductors 314 and 316 (carrying signal 3) and conductors 326 and 328 (carrying signal 6) are connected with a through-hole connection and are isolated from the embedded reference plane 304 through a dielectric layer.

In some example embodiments, a through-hole is connected to the embedded reference plane 304. For example, at reference points 330 and 332 the through-holes are connected to the embedded reference plane 304. As a result, the reference plane portions are then connected to the Vss or ground signal and sources.

In other example embodiments, the through-holes are not connected to the embedded reference plane. For example, points 334 and 336 show through-holes that connect an above signal to a signal on the underside of the package. As seen, a conductor carrying signal 6 on the top side 326 is connected through a PTH to a conductor 328 on the underside that is also carrying signal 6 (because the two conductors 326 and 328 are connected electrically). Thus, the embedded reference plane 304 does not affect the ability for signals to be connected from the top side to the underside.

Similarly, conductor 314 carries signal 3 and is connected electrically to conductor 316, which also carries signal 3 via a PTH that does not connect to the embedded reference plane 304, as seen at point 334.

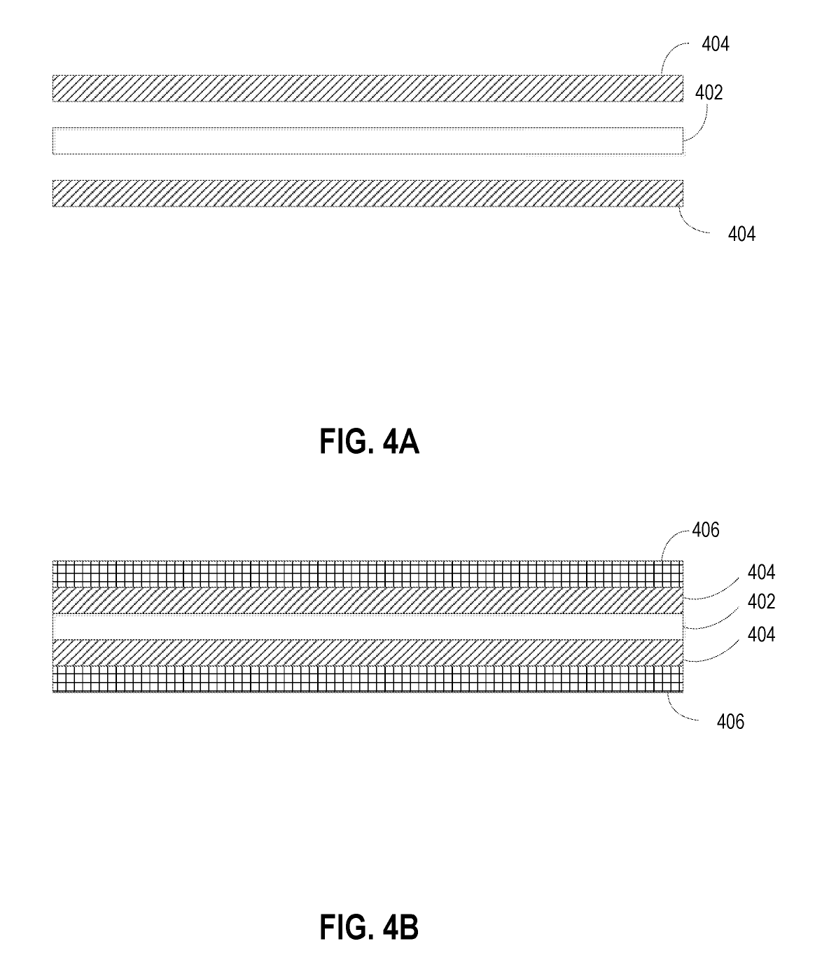

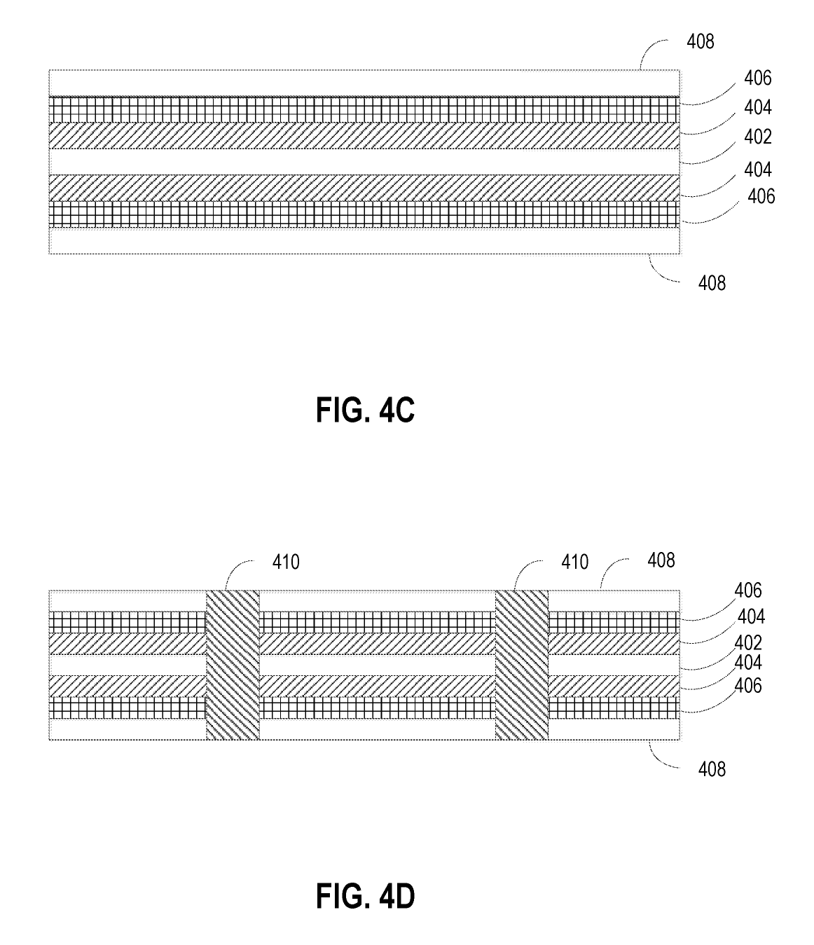

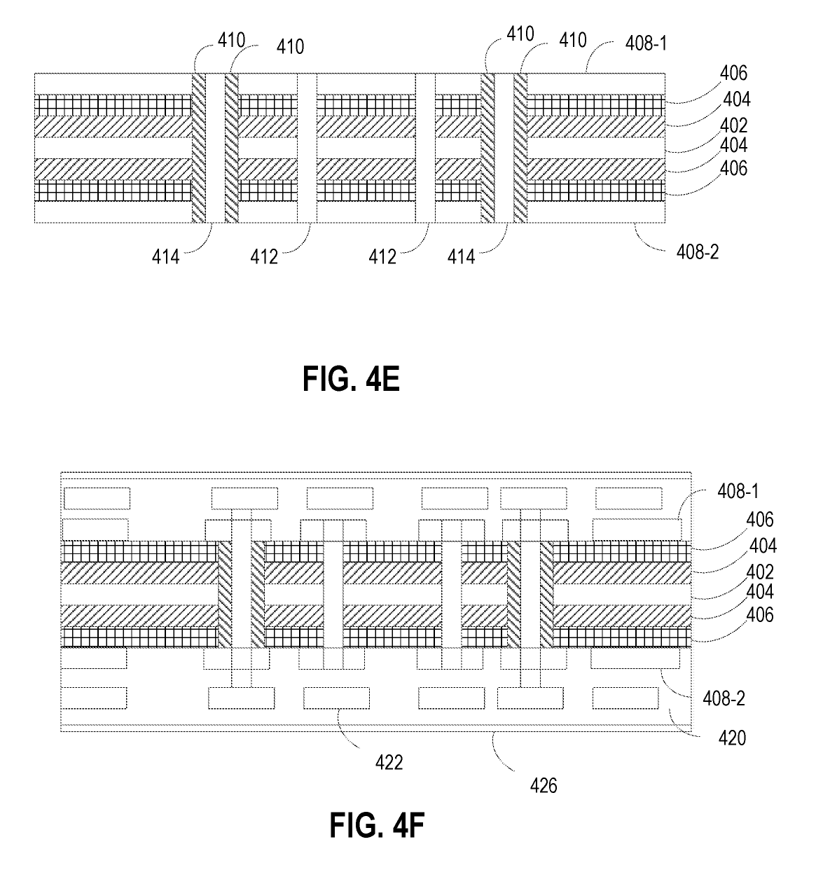

FIG. 4A is a diagram depicting one step in a process of fabricating a package substrate core layer with an embedded reference plane. In this step, two layers 404 of glass clothes are adhered to a metal conductive foil 402. In this example, the metal conductive foil 402 will serve as the metal reference plane.

In some example embodiments, the glass cloth layers 404 are affixed to either side of the metal conducive foil 402 through a lamination process. In some example embodiments, the lamination process is a hot press process. In other example embodiments, one or more instantiations of the glass cloth or metal conductive foil 402 may be used based on the electrical performance or mechanical requirements.

FIG. 4B is a diagram depicting one step in a process of fabricating a package substrate core layer with an embedded reference plane. In this step, the existing metal conductive foil 402 and glass cloth layers 404 are encapsulated with resin layers 406.

In some example embodiments, the metal conductive foil 402 and the surrounding glass cloth layers 404 are surrounded/encapsulated with a resin layer 406. In some example embodiments, the resin is a dielectric material such as polyimide, polyamide, bismaleimide-Triazine resin, epoxy resins, polyurethanes, benzocyclobutene (BCB), and high-density polyethylene (HDPE).

In some example embodiments, the dielectric material is added through an impregnation process such as lamination or rolling.

FIG. 4C is a diagram depicting one step in a process of fabricating a package substrate core layer with an embedded reference plane. In this step, the existing metal conductive foil 402, glass cloth layers 404, and resin layers 406 are laminated with an additional metal layer 408 (e.g., copper).

In some example embodiments, the additional metal layer 408 is added through a process of lamination and/or hot press. In some example embodiments, this metal layer 408 is used to enable signal redistribution and power transmission in the package when completed.

FIG. 4D is a diagram depicting one step in a process of fabricating a package substrate core layer with an embedded reference plane. In this step, the existing metal conductive foil 402, glass cloth layers 404, resin layers 406, and additional metal layer 408 (e.g., copper) are drilled through to create through-holes 410.

These through-holes 410 create separation between different sections of the metal conductive foil 402 and the metal layers 408. In some example embodiments, the through-holes 410 therefore enable different signals to be present in the different sections of the additional metal layers 408 and different sections of the embedded reference plane.

Each of the through-holes 410 can then be filled with a dielectric material (e.g., resin) to ensure that the different sections of metal are electrically and communicatively separated.

FIG. 4E is a diagram depicting one step in a process of fabricating a package substrate core layer with an embedded reference plane. In this step, the existing metal conductive foil 402, glass cloth layers 404, resin layers 406, and additional metal layer 408 (e.g., copper) are drilled through again to create additional or second through-holes 412, 414.

In some example embodiments, the additional or second through-holes 412 and 414 are drilled through the existing layers. Some of the additional or second through-holes 414 are drilled through a dielectric material that was deposited in the original or first through-holes (e.g., through-holes 410).

In some example embodiments, after the additional or second through-holes 412 and 414 are drilled, a metal layer is deposited through an electroplating process to establish vertical interconnects. These vertical interconnects connect the conductors on the upper layer (408-1) to conductors on the bottom layer (408-2) of the package substrate core layer. In this way, the conductors on the upper and the bottom layers can be configured and connected accordingly through the package substrate core and the embedded reference plane 402.

In some example embodiments, some vertical interconnects are electrically connected to the interior metal conductive foil layer (402). This way the metal conductive foil layer 402 can be configured to a reference voltage (e.g., Vss or ground). Other vertical interconnects are separated from the interior metal layer 402 by dielectric material (410). In this way, signals from the top layer conductors 408-1 will be isolated from the embedded reference plane 402 and communicated as needed to the bottom layer 408-2.

FIG. 4F is a diagram depicting one step in a process of fabricating a package substrate core layer with an embedded reference plane. In this step, the remaining components of the package are built up. The processes for accomplishing this include, but are not limited to, photolithography, etching, electroplating, and surface finishing process.

In some example embodiments, the package is encapsulated with additional dielectric material 420. In addition, more metal layers 422 can be added to further redistribute the signal routing within the package. In some example embodiments, a solder resist layer 426 is added as the final outer layer. In some example embodiments, these components are added through a process of photolithography, etching, electroplating, and surface finishing process.

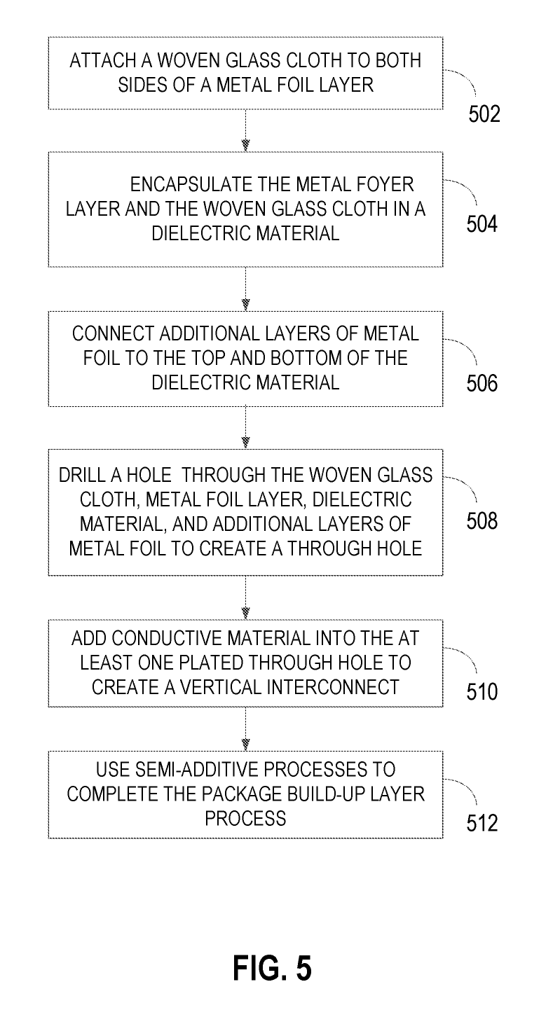

FIG. 5 shows a flow diagram of a method of fabricating a package substrate core layer with an embedded reference plane, in accordance with some example embodiments.

In some example embodiments, a woven glass cloth is attached (502) to both sides of a metal foil layer. In some example embodiments, the metal foil layer is copper. In other example embodiments, the metal foil layer is used as an embedded reference plane in a semiconductor package. In some example embodiments, this is accomplished using a lamination process or a hot press process.

In some example embodiments, the metal foil layer and the woven glass cloth are encapsulated (504) in a dielectric material. In some example embodiments, the dielectric material is a resin or a resin epoxy. In some example embodiments, the resin is added to the woven glass cloth layer via a lamination or rolling process.

In some example embodiments, addition layers of metal foil are connected (506) to the top and bottom of the dielectric material. In some example embodiments, the additional layer of metal foil will transmit data signals and power in the completed package. The additional metal foil is added to the package via lay-up and a hot press process.

In some example embodiments, at least one hole is drilled (508) through the woven glass cloth, metal foil layer, dielectric material, and additional layers of metal foil to create a through-hole (e.g. first through-hole). In some example embodiments, the hole is then filled with dielectric material. In other example embodiments, a new hole (e.g. second through-hole) is then drilled through the added dielectric material, resulting in a vertical hole that is lined with dielectric material. This helps insulate signal channels from the embedded reference voltage plane and is completed using a dielectric plugging process followed by mechanical drilling.

In some example embodiments, conductive material is added (510) into the at least one through-hole to create a vertical interconnect that attaches the metal foil layer to at least one of the additional layers of metal foil. In some example embodiments, semi-additive processes are used (512) to complete the package build-up layer process. The semi-additive processes included, but are not limited to, photolithography, etching, electroplating, and surface finishing processes.

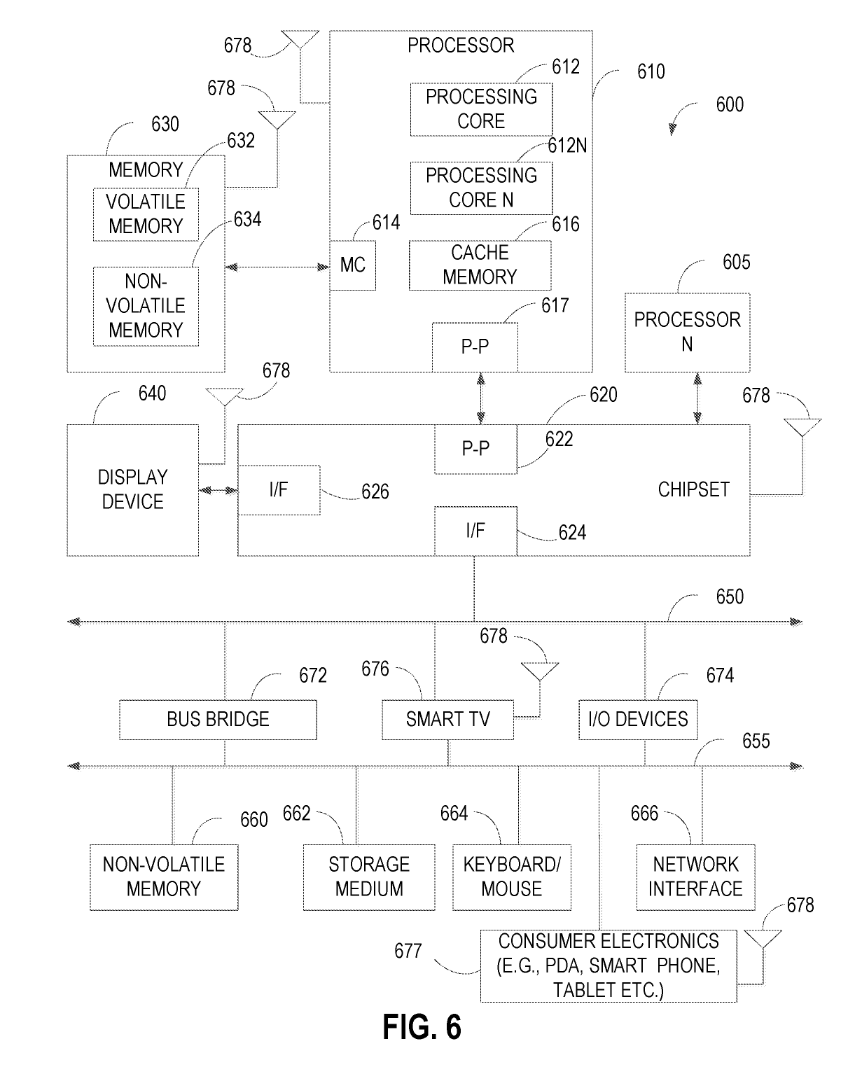

FIG. 6 illustrates a system-level diagram, according to one example embodiment. For instance, FIG. 6 depicts an example of an electronic device (e.g., system) 600 as described in the present disclosure. FIG. 6 is included to show an example of a higher-level device application. In one embodiment, the system 600 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 600 is a system-on-a-chip (SOC) system.

In one embodiment, processor 610 has one or more processing cores 612 and 612N, where 612N represents the nth processor core inside processor 610, where N is a positive integer. In one embodiment, system 600 includes multiple processors including 610 and 605, where processor 605 has logic similar or identical to the logic of processor 610. In some embodiments, processing core 612 includes, but is not limited to, pre-fetch logic to fetch instructions, decode logic to decode the instructions, execution logic to execute instructions, and the like. In some embodiments, processor 610 has a cache memory 616 to cache instructions and/or data for system 600. Cache memory 616 may be organized into a hierarchal structure including one or more levels of cache memory.

In some embodiments, processor 610 includes a memory controller 614, which is operable to perform functions that enable the processor 610 to access and communicate with memory 630 that includes a volatile memory 632 and/or a non-volatile memory 634. In some embodiments, processor 610 is coupled with memory 630 and chipset 620. Processor 610 may also be coupled to a wireless antenna 678 to communicate with any device configured to transmit and/or receive wireless signals. In one embodiment, the wireless antenna 678 operates in accordance with, but is not limited to, the IEEE 802.11 standard and its related family, Home Plug AV (HPAV), Ultra-Wide Band (UWB), Bluetooth, WiMax, or any form of wireless communication protocol.

In some embodiments, volatile memory 632 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 634 includes, but is not limited to, flash memory, phase change memory (PCM), read-only memory (ROM), electrically erasable programmable read-only memory (EEPROM), or any other type of non-volatile memory device.

Memory 630 stores information and instructions to be executed by processor 610. In one embodiment, memory 630 may also store temporary variables or other intermediate information while processor 610 is executing instructions. In the illustrated embodiment, chipset 620 connects with processor 610 via Point-to-Point (PtP or P-P) interfaces 617 and 622. Chipset 620 enables processor 610 to connect to other elements in system 600. In some embodiments, interfaces 617 and 622 operate in accordance with a PtP communication protocol such as the Intel® QuickPath Interconnect (QPI) or the like. In other embodiments, a different interconnect may be used.

In some embodiments, chipset 620 is operable to communicate with processors 610, 605; display device 640; and other devices 672, 676, 674, 660, 662, 664, 666, 677, and so forth. Chipset 620 may also be coupled to a wireless antenna 678 to communicate with any device configured to transmit and/or receive wireless signals.

Chipset 620 connects to display device 640 via interface 626. Display device 640 may be, for example, a liquid crystal display (LCD), a plasma display, cathode ray tube (CRT) display, or any other form of visual display device. In some embodiments, processor 610 and chipset 620 are merged into a single SOC. In addition, chipset 620 connects to one or more buses 650 and 655 that interconnect various elements 674, 660, 662, 664, and 666. Buses 650 and 655 may be interconnected together via a bus bridge 672. In one embodiment, chipset 620, via interface 624, couples with a non-volatile memory 660, a mass storage device(s) 662, a keyboard/mouse 664, a network interface 666, smart TV 676, consumer electronics 677, etc.

In one embodiment, mass storage device 662 includes, but is not limited to, a solid state drive, a hard disk drive, a universal serial bus flash memory drive, or any other form of computer data storage medium. In one embodiment, network interface 666 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, HPAV, UWB, Bluetooth, WiMax, or any form of wireless communication protocol.

While the modules shown in FIG. 6 are depicted as separate blocks within the system 600, the functions performed by some of these blocks may be integrated within a single semiconductor circuit or may be implemented using two or more separate integrated circuits. For example, although cache memory 616 is depicted as a separate block within processor 610, cache memory 616 (or selected aspects of memory 616) may be incorporated into processing core 612.

### Additional Notes and Examples

Example 1 is a semiconductor package designed to minimize thickness, the semiconductor package comprising a multilayer package substrate, wherein the layers of the multi-layer substrate include: one or more conductive layers to transmit information within the semiconductor package; one or more conductive power supply layers to provide power to the semiconductor package and to one or more connected components; one or more layers of dielectric material forming a substrate core dielectric; and an embedded reference plane within the substrate core dielectric, wherein the embedded reference plane is conductive and reduces electrical interference between the other conductive layers in the multilayer package substrate.

In Example 2, the subject matter of Example 1 wherein optionally the embedded reference plane is comprised of copper.

In Example 3, the subject matter of Example 1 wherein optionally the embedded reference plane is connected to Vss or ground reference voltage.

In Example 4, the subject matter of Example 1 wherein optionally the embedded reference plane is connected to a reference voltage source via one of the reference voltage traces and vertical interconnects.

In Example 5, the subject matter of Example 1 wherein optionally the dielectric material is one of polyimide, polyamide, bismaleimide-Triazineresin, epoxy resins, polyurethanes, benzocyclobutene (BCB), and high-densitypolyethylene (HDPE).

In Example 6, the subject matter of Example 1 wherein optionally the package is connected to another component via a ball grid array.

In Example 7, the subject matter of Example 1 wherein optionally the one or more conductive layers to transmit information within the semiconductor package are isolated from the embedded reference plane.

Example 8 is a method of constructing a semiconductor package, the method comprising attaching a woven glass cloth to both sides of a metal foil layer; encapsulating the metal foil layer and the woven glass cloth in a dielectric material; connecting additional layers of metal foil to the top and bottom of the dielectric material; drilling at least one hole through the woven glass cloth, metal foil layer, dielectric material, and additional layers of metal foil to create at least one through-hole; adding conductive material into the at least one through-hole to create a vertical interconnect that attaches the metal foil layer to at least one of the additional layers of metal foil; and using semi-additive processes to complete a package build-up layer process.

In Example 9, the subject matter of Example 8 wherein optionally the metal foil layer is copper.

In Example 10, the subject matter of Example 8 wherein optionally the woven glass cloth is attached to the metal foil layer using a hot press process.

In Example 11, the subject matter of Example 8 wherein optionally the semi-additive processes include, but are not limited to, photolithography, etching, electroplating, and surface finishing processes.

In Example 12, the subject matter of Example 8 wherein optionally a lamination process is used to encapsulate the metal foil layer and the woven glass cloth in a dielectric material.

In Example 13, the subject matter of Example 11 wherein optionally some vertical interconnects are insulated from the metal foil layer using a layer of dielectric material laid down after the at least one through-hole is drilled through the semiconductor package.

In Example 14, the subject matter of Example 8 wherein optionally the dielectric material is an epoxy resin.

Example 15 is a semiconductor package, the semiconductor package comprising: a metal foil layer; a first and second glass cloth layers attached to both sides of the metal foil layer; a dielectric material encapsulating the metal foil layer and the woven glass cloth in a dielectric material; additional layers of metal foil attached to the top and bottom of the dielectric material; at least one through hole created by drilling a hole through the woven glass cloth, metal foil layer, dielectric material, and additional layers of metal foil; a vertical interconnect made of conductive material in the at least one through hole that attaches the metal foil layer to at least one of the additional layers of metal foil.

In Example 16, the subject matter of Example 15 wherein optionally the metal foil layer is copper.

In Example 17, the subject matter of Example 15 wherein optionally the woven glass cloth is attached to the metal foil layer using a hot press process.

In Example 18, the subject matter of Example 18 wherein optionally some vertical interconnects are insulated from the metal foil layer using a layer of dielectric material laid down after the at least one through-hole is drilled through the semiconductor package.

In Example 19, the subject matter of Example 15 wherein optionally the dielectric material is an epoxy resin.

Example 20 is an apparatus comprising means for performing any of the methods of examples 8-14.

Example 21 is an apparatus for constructing a semiconductor package, the apparatus comprising: means for attaching a woven glass cloth to both sides of a metal foil layer; means for encapsulating the metal foil layer and the woven glass cloth in a dielectric material; means for connecting additional layers of metal foil to the top and bottom of the dielectric material; means for drilling at least one hole through the woven glass cloth, metal foil layer, dielectric material, and additional layers of metal foil to create at least one through-hole; means for adding conductive material into the at least one through-hole to create a vertical interconnect that attaches the metal foil layer to at least one of the additional layers of metal foil; and means for using semi-additive processes to complete a package build-up layer process.

In Example 22, the subject matter of Example 21 wherein optionally the metal foil layer is copper.

In Example 23, the subject matter of Example 21 wherein optionally the woven glass cloth is attached to the metal foil layer using a hot press process.

In Example 24, the subject matter of Example 21 wherein optionally the semi-additive processes include, but are not limited to, photolithography, etching, electroplating, and surface finishing processes.

In Example 25, the subject matter of Example 22 wherein optionally a lamination process is used to encapsulate the metal foil layer and the woven glass cloth in a dielectric material.

In Example 26, the subject matter of Example 24 wherein optionally some vertical interconnects are insulated from the metal foil layer using a layer of dielectric material laid down after the at least one through-hole is drilled through the semiconductor package.

In Example 27, the subject matter of Example 21 wherein optionally the dielectric material is an epoxy resin.

### Term Usage

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

1. A semiconductor package designed to minimize thickness, the semiconductor package comprising:
a multilayer package substrate, wherein the layers of the multi-layer substrate include:
one or more conductive layers to transmit information within the semiconductor package;
one or more conductive power supply layers to provide power to the semiconductor package and to one or more connected components;
one or more layers of dielectric material forming a substrate core dielectric; and
an embedded reference plane within the substrate core dielectric, wherein the embedded reference plane is conductive and reduces electrical interference between the other conductive layers in the multilayer package substrate.

2. The semiconductor package of claim 1, wherein the embedded reference plane is comprised of copper.

3. The semiconductor package of claim 1, wherein the embedded reference plane is connected to Vss or ground reference voltage.

4. The semiconductor package of claim 1, wherein the embedded reference plane is connected to a reference voltage source via one of the reference voltage traces and vertical interconnects.

5. The semiconductor package of claim 1, wherein the dielectric material is one of polyimide, polyamide, bismaleimide-Triazineresin, epoxy resins, polyurethanes, benzocyclobutene (BCB), and high-densitypolyethylene (HDPE).

6. The semiconductor package of claim 1, wherein the package is connected to another component via a ball grid array.

7. The semiconductor package of claim 1, wherein the one or more conductive layers to transmit information within the semiconductor package are isolated from the embedded reference plane.

8. A method of constructing a semiconductor package, the method comprising:
attaching a woven glass cloth to both sides of a metal foil layer;
encapsulating the metal foil layer and the woven glass cloth in a dielectric material;
connecting additional layers of metal foil to the top and bottom of the dielectric material;
drilling at least one hole through the woven glass cloth, metal foil layer, dielectric material, and additional layers of metal foil to create at least one through-hole;
adding conductive material into the at least one through-hole to create a vertical interconnect that attaches the metal foil layer to at least one of the additional layers of metal foil; and
using semi-additive processes to complete a package build-up layer process.

9. The method of claim 8, wherein the metal foil layer is copper.

10. The method of claim 8, wherein the woven glass cloth is attached to the metal foil layer using a hot press process.

11. The method of claim 8, wherein the semi-additive processes include, but are not limited to, photolithography, etching, electroplating, and surface finishing processes.

12. The method of claim 8, wherein a lamination process is used to encapsulate the metal foil layer and the woven glass cloth in a dielectric material.

13. The method of claim 11, wherein some vertical interconnects are insulated from the metal foil layer using a layer of dielectric material laid down after the at least one through-hole is drilled through the semiconductor package.

14. The method of claim 8, wherein the dielectric material is an epoxy resin.

15. A semiconductor package, the semiconductor package comprising:
a metal foil layer;
a first and second glass cloth layers attached to both sides of the metal foil layer;
a dielectric material encapsulating the metal foil layer and the woven glass cloth in a dielectric material;
additional layers of metal foil attached to the top and bottom of the dielectric material;
at least one through hole created by drilling a hole through the woven glass cloth, metal foil layer, dielectric material, and additional layers of metal foil;
a vertical interconnect made of conductive material in the at least one through hole that attaches the metal foil layer to at least one of the additional layers of metal foil.

16. The semiconductor package of claim 15, wherein the metal foil layer is copper.

17. The semiconductor package of claim 15, wherein the woven glass cloth is attached to the metal foil layer using a hot press process.

18. The semiconductor package of claim 15, wherein a lamination process is used to encapsulate the metal foil layer and the woven glass cloth in a dielectric material.

19. The semiconductor package of claim 15, wherein the dielectric material is an epoxy resin.
